(19) United States
(12) Patent Application Publication
(10) Pub. No.: US 2026/0072073 A1
(43) Pub. Date: Mar. 12, 2026

(54) DETECTION DEVICE OF DISPLAY PANEL AND DETECTION METHOD THEREOF

(71) Applicant: AUO Corporation, Hsinchu City (TW)

(72) Inventors: Jyun Jhih Lin, Hsinchu City (TW); Jeng-Yi Huang, Hsinchu City (TW); Yen-Yu Chen, Hsinchu City (TW)

(73) Assignee: AUO Corporation, Hsinchu City (TW)

(21) Appl. No.: 18/935,624

(22) Filed: Nov. 3, 2024

(30) Foreign Application Priority Data
Sep. 11, 2024 (TW) 113134401

(51) Int. Cl. G01R 31/28; G01R 31/00

(52) U.S. Cl. CPC G01R 31/2825; G01R 31/006

(57) ABSTRACT

A detection device of a display panel and a detection method thereof are provided. The display panel is installed on the front of a vehicle and displays the vehicle logo while the vehicle is running. The detection device includes a current sensing circuit, an analog-to-digital converter, and a determination circuit. The current sensing circuit receives a total panel current flowing through the display panel to provide a current characteristic voltage. The analog-to-digital converter coupled to the current sensing circuit to provide current characteristic data based on the current characteristic voltage. The determination circuit is coupled to the analog-to-digital converter, and determines whether the display panel operates within a rated chromaticity range based on the current characteristic data to provide a panel status signal.

### CROSS-REFERENCE TO RELATED APPLICATION

This application claims the priority benefit of Taiwan application serial no. 113134401, filed on Sep. 11, 2024. The entirety of the above-mentioned patent application is hereby incorporated by reference herein and made a part of this specification.

### BACKGROUND

### Technical Field

The disclosure relates to a detection device, and particularly relates to a detection device of a display panel and a detection method thereof.

### Description of Related Art

The display installed on the front of the vehicle is limited to only displaying the logo of the car manufacturer during vehicle operation. Complying with the color gamut regulations for vehicle lights necessarily, the chromaticity displayed by the display ensures not to cause visual discomfort or affect safety for drivers or road users. Therefore, how to determine if the chromaticity displayed by the display remains within the color gamut regulations for vehicle lights is an important issue for display devices used to show car logos.

### SUMMARY

The disclosure provides a detection device of a display panel and a detection method thereof, which can determine the operating status of the display panel.

A detection device of a display panel of the disclosure, where the display panel is installed on a front of a vehicle and displays a car logo while the vehicle is running, includes a current sensing circuit, an analog-to-digital converter (ADC), and a determination circuit. The current sensing circuit receives a total panel current flowing through the display panel to provide a current characteristic voltage. The ADC is coupled to the current sensing circuit to provide current characteristic data based on the current characteristic voltage. The determination circuit is coupled to the ADC and determines whether the display panel operates within a rated chromaticity range based on the current characteristic data to provide a panel status signal.

A detection method of a display panel of the disclosure, where the display panel is installed on a front of the vehicle and displays a car logo while the vehicle is running, includes the following steps. A total panel current flowing through the display panel is received via a current sensing circuit to provide a current characteristic voltage. Current characteristic data is provided via an analog-to-digital converter based on the current characteristic voltage. Whether the display panel operates within a rated chromaticity range is determined via a determination circuit based on the current characteristic data to provide a panel status signal.

Based on the above, in the detection device of the display panel and the detection method thereof according to the embodiments of the disclosure, the detection device may detect minute changes in the total panel current of the display panel, thereby determining the operating status of the display panel to determine whether the damage to the light-emitting diode pixels in the display panel exceeds the allowable value. Moreover, since the detection device converts the current waveform to digital values for determination, the detection device can achieve the purpose of determining the operating status of the display panel with a lower hardware cost by using the ADC with a lower sampling rate and a determination circuit with lower computational power.

To make the above-mentioned features and advantages of the disclosure comprehensible, exemplary embodiments are described below with reference to the accompanying drawings as follows.

### BRIEF DESCRIPTION OF THE DRAWINGS

FIG. 1 is a system diagram illustrating a detection device of a display panel according to an embodiment of the disclosure.

FIG. 2 is a system diagram illustrating a current sensing circuit of a detection device according to an embodiment of the disclosure.

FIG. 3 is a circuit diagram illustrating a current sensing circuit of a detection device according to an embodiment of the disclosure.

FIG. 4A to FIG. 4D are voltage waveform diagrams illustrating a current sensing circuit of a detection device according to an embodiment of the disclosure.

FIG. 5 is a flowchart illustrating a detection method of a display panel according to an embodiment of the disclosure.

FIG. 6 is a flowchart illustrating an operation method of a vehicle infotainment system with a display panel showing a car logo according to an embodiment of the disclosure.

### DESCRIPTION OF THE EMBODIMENTS

The terms “about,” “approximately,” “essentially,” or “substantially” used in the disclosure include the stated value and average values within an acceptable deviation range as determined by ordinary skilled persons in the field, considering the specific quantity of the measurements discussed and the errors associated with the measurements (that is, limitations of the measurement system). For example, “about” may indicate within one or more standard deviations of the stated value, or for instance, within ±30%, ±20%, ±15%, ±10%, ±5%. Furthermore, the terms “about,” “approximately,” “essentially,” or “substantially” used in the disclosure may be selected with a more acceptable deviation range or standard deviation according to the nature of measurement, nature of cutting, or other properties, rather than applying a single standard deviation to all properties.

In the drawings, the thickness of layers, films, panels, regions, etc., are exaggerated for clarity. It should be understood that when an element such as a layer, film, region, or substrate is referred to as being “on” or “connected to” another element, it may be directly on or connected to the other element, or intervening elements may also be present. In contrast, when an element is referred to as being “directly on” or “directly connected to” another element, there are no intervening elements present. As used herein, “connected” may refer to physical and/or electrical connection. Furthermore, “electrically connected” may mean that other elements exist between two elements.

Moreover, relative terms such as “below” or “bottom” and “above” or “top” may be used herein to describe a relationship of one element with another element as illustrated in the figures. It should be understood that relative terms are intended to encompass different orientations of the device in addition to the orientation depicted in the figures. For example, if a device in one of the figures is turned over, elements described as being on the “below” side of other elements would then be oriented “above” the other elements. Thus, the exemplary term “below” may encompass both an orientation of “below” and “above”, depending on the particular orientation of the figure. Similarly, if a device in one of the figures is turned over, elements described as “beneath” or “under” other elements would be oriented “over” the other elements. Thus, the exemplary terms “above” or “below” may encompass both over and under orientations.

The exemplary embodiments are described herein with reference to cross-sectional illustrations that are schematic illustrations of idealized embodiments. As such, variations from the shapes of the illustrations as a result of, for example, manufacturing techniques and/or tolerances, are to be expected. Thus, the embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the claims.

Exemplary embodiments of the disclosure will now be described in detail, examples of which are illustrated in the accompanying drawings. Wherever possible, the same reference numbers are used in the drawings and the description to refer to the same or similar parts.

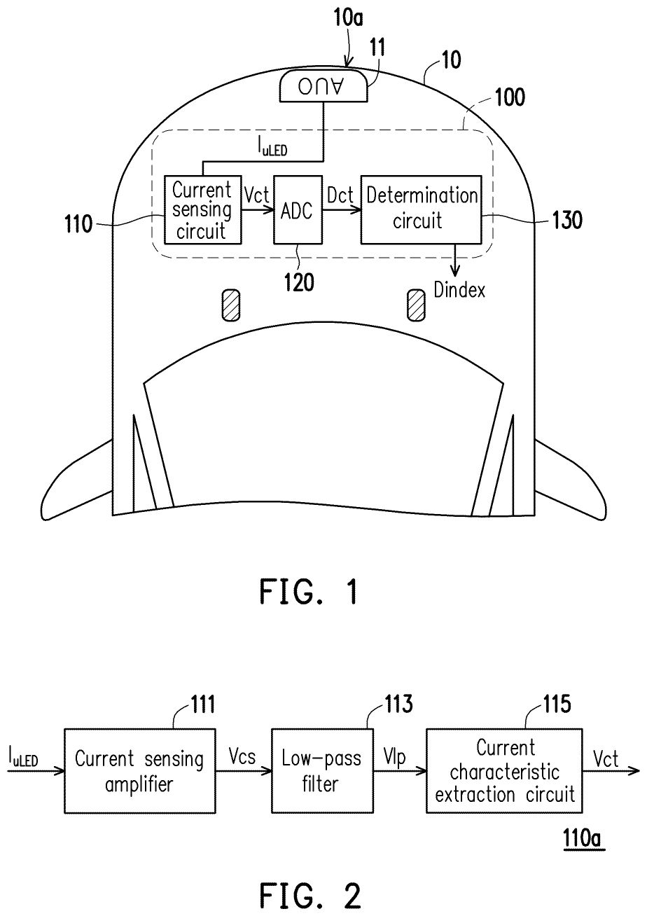

FIG. 1 is a system diagram illustrating a detection device of a display panel according to an embodiment of the disclosure. Referring to FIG. 1, in this embodiment, a display panel 11 may be installed on a front 10a of a vehicle 10 and display a car logo (such as displaying AUO) while the vehicle 10 is running. A detection device 100 includes a current sensing circuit 110, an analog-to-digital converter (ADC) 120, and a determination circuit 130, where the display panel 11 may be a display panel with an LED array.

The current sensing circuit 110 receives a panel total current I_{uLED} flowing through the display panel 11 to provide a current characteristic voltage Vct based on the received panel total current I_{uLED}, where the panel total current I_{uLED} may vary with time based on the writing status (or display status) of the display panel 11. However the current characteristic voltage Vct maintains a single voltage level (that is, DC) in a unit time (that is, a sensing cycle).

The ADC 120 is coupled to the current sensing circuit 110 to provide current characteristic data Dct based on the current characteristic voltage Vct, for example, converting the analog current characteristic voltage Vct to digital current characteristic data Dct. The current characteristic voltage Vct presents as DC in a unit time; therefore, the ADC 120 may execute once in a unit time, reducing the number of executions and power consumption.

The determination circuit 130 is coupled to the ADC 120, and determines whether the display panel 11 operates within the rated chromaticity range (that is, the specified color and brightness) based on the current characteristic data Dct, to provide a panel status signal Dindex. Further, when the display panel 11 maintains the specified color and brightness, the waveform of the panel total current I_{uLED} is approximately the same. In other words, the current characteristic data Dct is approximately the same as the factory value calculated based on the waveform measured at the factory. At this time, the panel status signal Dindex may indicate that the display panel 11 is normal. Conversely, when the display panel 11 gradually deviates and exceeds the specified color and brightness due to aging or malfunction, the waveform of the panel total current I_{uLED} fluctuates significantly. In other words, the current characteristic data Dct may have a larger difference (that is, difference value) from the factory value. At this time, the panel status signal Dindex may indicate that the display panel 11 is abnormal.

According to the above, in the case of damaged LED pixels in the display panel 11, the detection device 100 may detect minute current changes in the display panel 11, thereby determining the operating status of the display panel 11. Moreover, since the detection device 100 may execute one detection in a unit time, the detection device 100 may achieve the purpose of determining the operating status of the display panel 11 with a lower hardware cost by using an ADC 120 with a lower sampling rate and a determination circuit 130 with lower computing power.

In this embodiment of the disclosure, when the difference between the current characteristic data Dct and a panel preset value set at the factory for the display panel 11 is less than a threshold value, the panel status signal Dindex indicates that the display panel 11 operates within the rated chromaticity range (that is, normal status). When the difference between the current characteristic data Dct and the panel preset value is greater than or equal to the threshold value, the panel status signal Dindex indicates that the display panel 11 operates outside the rated chromaticity range (that is, abnormal status).

In this embodiment of the disclosure, the display panel 11 may be, for example, an organic light-emitting diode (OLED) display panel, a mini light-emitting diode (Mini LED) display panel, a micro light-emitting diode (uLED) display panel, etc., but this embodiment of the disclosure is not limited to thereto.

In this embodiment of the disclosure, the determination circuit 130 may include, for example, a microcontroller unit (MCU) and/or a processor, but this embodiment of the disclosure is not limited to thereto.

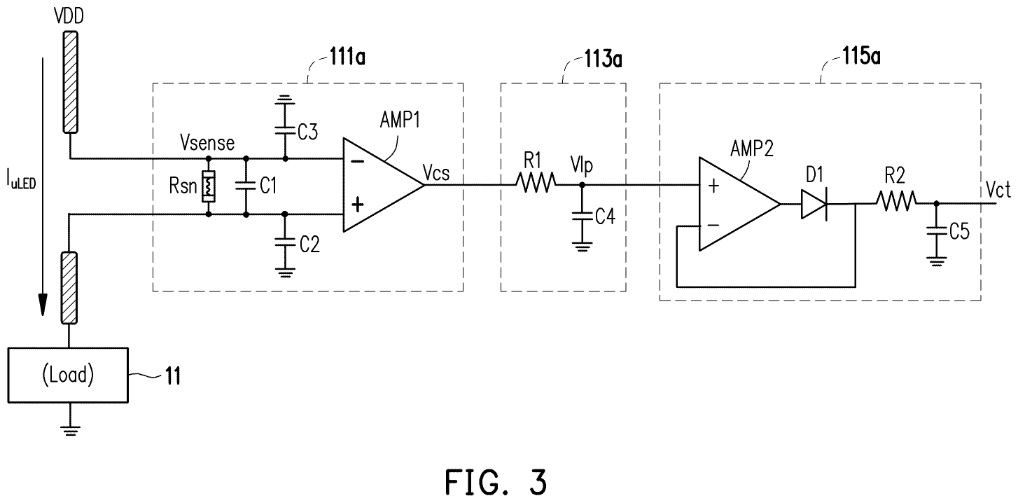

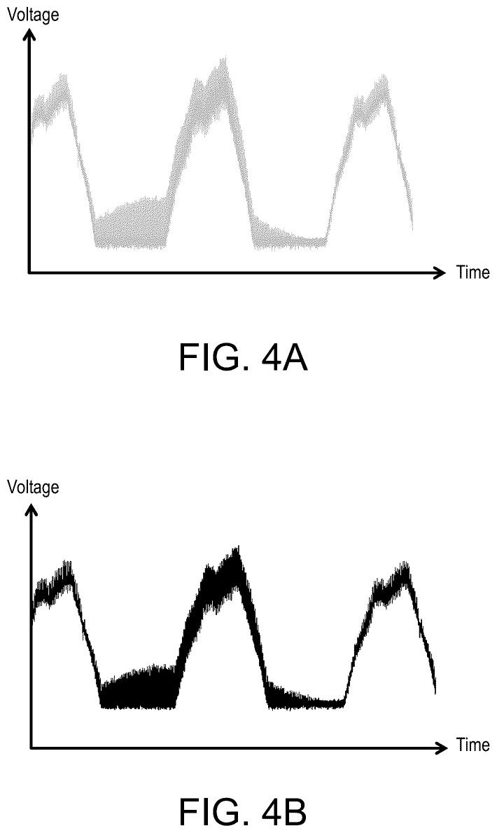

FIG. 2 is a system diagram illustrating a current sensing circuit of a detection device according to an embodiment of the disclosure. Referring to FIG. 1 and FIG. 2, in this embodiment, a current sensing circuit 110a includes a current sensing amplifier 111, a low-pass filter 113, and a current characteristic extraction circuit 115. The current sensing amplifier 111 amplifies a sensing voltage (such as the sensing voltage Vsense shown in FIG. 3) based on the panel total current I_{uLED} to provide a current sensing voltage Vcs. The low-pass filter 113 is coupled to the current sensing amplifier 111 to provide a filtered voltage Vlp based on the current sensing voltage Vcs. The current characteristic extraction circuit 115 is coupled to the low-pass filter 113 to provide a current characteristic voltage Vct based on the filtered voltage Vlp.

FIG. 3 is a circuit diagram illustrating a current sensing circuit of a detection device according to an embodiment of the disclosure. Referring to FIG. 1, FIG. 2, and FIG. 3, in this embodiment, a current sensing amplifier 111a may include, for example, a differential amplifier AMP1 (corresponding to the first differential amplifier) and capacitors C1 to C3 (corresponding to the first capacitor to the third capacitor). A sensing resistor Rsn is coupled in series with the display panel 11 between a system high voltage VDD and a ground voltage to provide the sensing voltage Vsense, where the display panel 11 is a load to the current sensing amplifier 111.

The differential amplifier AMP1 has a positive input terminal receiving the sensing voltage, a negative input terminal, and an output terminal providing the current sensing voltage Vcs. The capacitor C1 is coupled between the positive input terminal of the differential amplifier AMP1 and the negative input terminal of the differential amplifier AMP1. The capacitor C2 is coupled between the positive input terminal of the differential amplifier AMP1 and the ground voltage. The capacitor C3 is coupled between the negative input terminal of the differential amplifier AMP1 and the ground voltage.

In this embodiment, a low-pass filter 113a may include, for example, a resistor R1 (corresponding to the first resistor) and a capacitor C4 (corresponding to the fourth capacitor). The resistor R1 is coupled between the current sensing voltage Vcs and the filtered voltage Vlp. The capacitor C4 is coupled between the filtered voltage Vlp and the ground voltage.

In this embodiment, a current characteristic extraction circuit 115a may include, for example, a differential amplifier AMP2 (corresponding to the second differential amplifier), a diode D1 (corresponding to the first diode), a resistor R2 (corresponding to the second resistor), and a capacitor C5 (corresponding to the fifth capacitor). The differential amplifier AMP2 has a positive input terminal receiving the filtered voltage Vlp, a negative input terminal, and an output terminal. The diode D1 has an anode coupled to the output terminal of the differential amplifier AMP2, and a cathode coupled to the negative input terminal of the differential amplifier AMP2. The resistor R2 is coupled between the negative input terminal of the differential amplifier AMP2 and the current characteristic voltage Vct. The capacitor C5 is coupled between the current characteristic voltage Vct and the ground voltage.

In this embodiment of the disclosure, a resistance value of the resistor R2 and/or a capacitance value of the capacitor C5 in the current characteristic extraction circuit 115a may be adjusted according to the characteristics of the displayed car logo (such as the displayed AUO) to increase the sensitivity to the current waveform of the panel total current I_{uLED} flowing through the display panel 11.

In this embodiment of the disclosure, the current characteristic voltage Vct reflects one of the maximum voltage, minimum voltage, and average value of the sensing voltage Vsense generated by the panel total current I_{uLED} flowing through the sensing resistor Rsn during the sensing period (for example, at least one frame period).

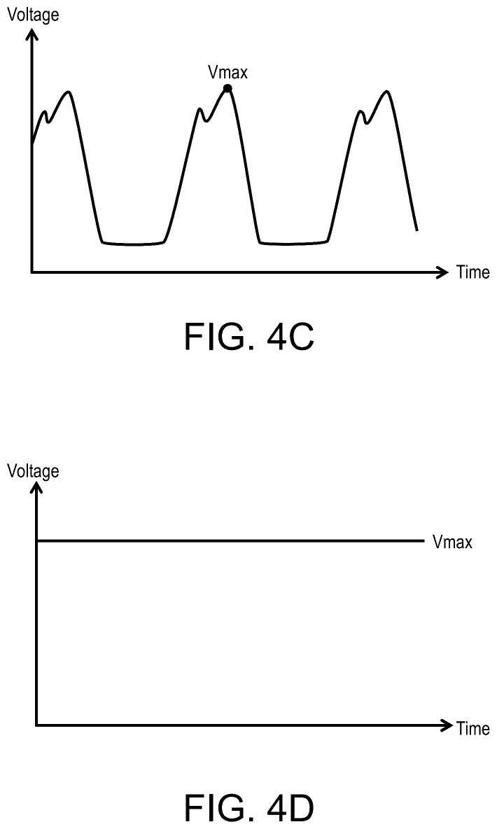

FIG. 4A to FIG. 4D are voltage waveform diagrams illustrating a current sensing circuit of a detection device according to an embodiment of the disclosure. Referring to FIG. 1 to FIG. 4, in this embodiment, FIG. 4A shows the voltage waveform of the sensing voltage Vsense, FIG. 4B shows the voltage waveform of the current sensing voltage Vcs, FIG. 4C shows the voltage waveform of the filtered voltage Vlp, and FIG. 4D shows the voltage waveform of the current characteristic voltage Vct. In this embodiment, the current characteristic voltage Vct reflects the maximum voltage Vmax of the sensing voltage Vsense generated by the panel total current I_{uLED} flowing through the sensing resistor Rsn during the sensing period, but the embodiment of the disclosure is not limited to thereto.

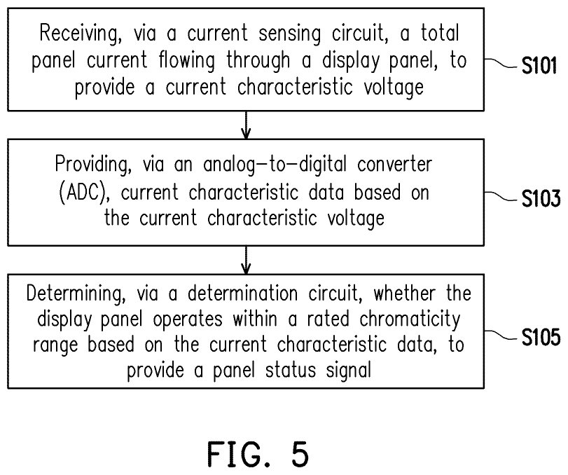

FIG. 5 is a flowchart illustrating a detection method of a display panel according to an embodiment of the disclosure. Referring to FIG. 5, in this embodiment, the display panel is installed on the front of the vehicle and displays the car logo while the vehicle is running. The detection method includes the following steps. In step S101, the panel total current flowing through the display panel is received via the current sensing circuit to provide the current characteristic voltage. In step S103, the current characteristic data is provided by the ADC based on the current characteristic voltage. Moreover, in step S105, the panel status signal is provided by the determination circuit determining whether the display panel operates within the rated chromaticity range based on the current characteristic data. The order of steps S101, S103, and S105 is for illustration purposes, and the embodiment of the disclosure is not limited to thereto. Additionally, the details of steps S101, S103, and S105 may refer to FIG. 1 to FIG. 3 and FIG. 4A to FIG. 4D, which is not repeated here.

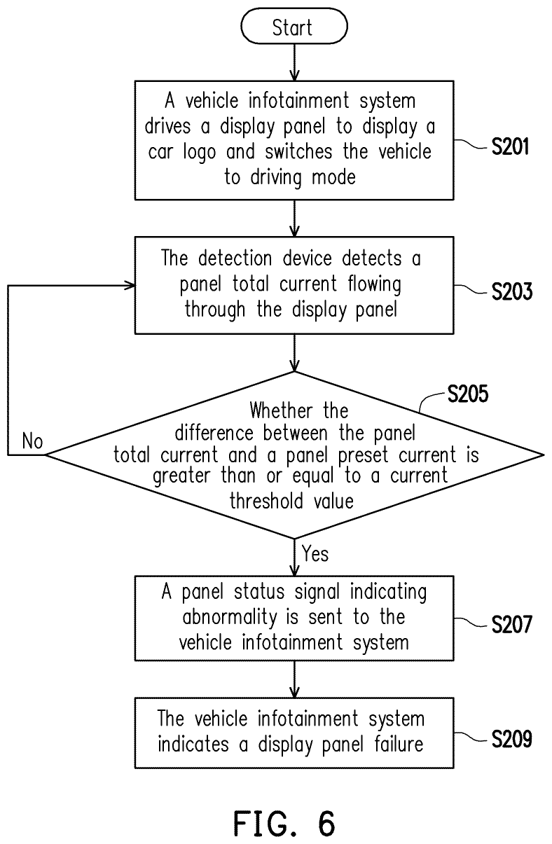

FIG. 6 is a flowchart illustrating an operation method of a vehicle infotainment system with a display panel showing a car logo according to an embodiment of the disclosure. Referring to FIG. 6, in this embodiment, the operation method includes the following steps. In step S201, the vehicle infotainment system drives the display panel to display the car logo and switches the vehicle to running mode. In step S203, the detection device detects the panel total current flowing through the display panel.

In step S205, it is determined whether the difference between the panel total current and the panel preset current is greater than or equal to a current threshold value. When the difference between the panel total current and the panel preset current is not greater than or equal to the current threshold value, the process returns to step S203 to continuously detect the panel total current. When the difference between the panel total current and the panel preset current is greater than or equal to the current threshold value, step S207 is executed.

In step S207, a panel status signal indicating abnormality is sent to the vehicle infotainment system, and in step S209, the vehicle infotainment system indicates a display panel failure to prompt the user to perform inspection/maintenance.

In the detection device of the display panel and the detection method thereof according to an embodiment of the disclosure, the characteristics of the current waveform of the display panel 11 displaying the car logo may be identified and converted into corresponding digital values, and the difference in driving current when dozens of bad pixels occur in the display panel 11 may be detected. Furthermore, based on the fault current range defined by the user, a panel status signal Dindex indicating whether a fault has occurred may be sent back in real-time, where the panel status signal Dindex may include a diagnostic trouble code (DTC).

In this embodiment of the disclosure, the current sensing amplifier 111 is configured to measure and amplify the current signal flowing through the display panel 11, and the main purpose is to convert the measured current signal into a voltage signal for accurate current measurement, control, or feedback control. By adjusting the gain value for the front-end small resistance, the accuracy of current measurement may be increased.

In this embodiment of the disclosure, the low-pass filter 113 may be configured to remove high-frequency oscillations or noise from the current waveform of the panel total current I_{uLED} flowing through the display panel 11. In this application, the low-pass filter 113 is configured to reduce the interference of high-frequency noise in the current characteristic voltage Vct on the subsequent current characteristic extraction circuit 115.

In this embodiment of the disclosure, the ADC 120 converts the analog voltage corresponding to the original current into a digital signal to facilitate data transmission and computation by the determination circuit 130.

In this embodiment of the disclosure, the purpose of the current characteristic extraction circuit 115 is to identify the characteristics of the current waveform flowing through the display panel 11 displaying the car logo, and to respond immediately even when there is a slight difference in current. Basically, there are many methods to identify the characteristics of the current waveform flowing through the display panel 11 displaying the car logo, such as using an integral circuit for total current calculation, using data retrieved by the ADC for slope and differential calculations, establishing a characteristic matrix, and so on. However, the above methods are all difficult to implement.

In this embodiment of the disclosure, the detection device 100 may detect the peak value of the current waveform, and increase the sensitivity to current changes by matching the RC values at the output terminal, so that the changes between the waveforms of each current scan are less drastic, but may still respond immediately when there is a difference in current. Regarding the RC time constant of the circuit output, a larger RC time constant may make the output smoother, while a smaller RC time constant may make the output more sensitive.

TABLE 1

| | | |
|---|---|---|
| Simulation of | | Average value of the |
| number of | Oscilloscope | total panel current of |
| damaged sub- | average value | the detection device |

| pixels | V | mA | V | mA |
|---|---|---|---|---|
| all white | 1.3253 | 265.06 | 1.308 | 261.6 |
| red 25 | 1.3218 | 264.36 | 1.3044 | 260.88 |
| red 50 | 1.3171 | 263.42 | 1.2997 | 259.94 |
| red 75 | 1.3125 | 262.5 | 1.2956 | 259.12 |
| red 100 | 1.3076 | 261.52 | 1.2908 | 258.16 |
| green 25 | 1.3212 | 264.24 | 1.3038 | 260.76 |
| green 50 | 1.3183 | 263.66 | 1.3009 | 260.18 |
| green 75 | 1.3161 | 263.22 | 1.2986 | 259.72 |
| green 100 | 1.3145 | 262.9 | 1.2966 | 259.32 |
| blue 25 | 1.3231 | 264.62 | 1.3055 | 261.1 |
| blue 50 | 1.3218 | 264.36 | 1.3043 | 260.86 |
| blue 75 | 1.3198 | 263.96 | 1.3026 | 260.52 |
| blue 100 | 1.3180 | 263.6 | 1.3001 | 260.02 |

Table 1 shows the ability of the detection device 100 to identify the damage condition of sub-pixels. The experimental variables are: 1) the number of damaged points of sub-pixels; 2) the color of sub-pixels: red/green/blue.

It may be observed that the current-converted corresponding voltage has a linear decreasing relationship with the number of damaged points. Additionally, the characteristics of light-emitting diodes of different colors may be observed, namely, the current consumption of light-emitting diodes is: red>green>blue.

In summary, in the detection device of the display panel and the detection method thereof according to this embodiment of the disclosure, the detection device may detect minute changes in the total panel current of the display panel, thereby determining the operating status of the display panel to judge whether the damage condition of the light-emitting diode pixels in the display panel exceeds the allowable value. Moreover, since the detection device converts the current waveform into digital values for determination, the detection device may achieve the purpose of determining the operating status of the display panel with the lower hardware cost by using the ADC with the lower sampling rate and the determination circuit with the lower computing power.

Although the disclosure has been disclosed as above with embodiments, it is not intended to limit the disclosure. Any person skilled in the art may make some modifications and refinements without departing from the spirit and scope of the disclosure. Therefore, the protection scope of the disclosure should be defined by the appended claims.

What is claimed is:

1. A detection device of a display panel installed on a front of a vehicle and displaying a car logo while the vehicle is running, comprising:
a current sensing circuit, receiving a panel total current flowing through the display panel, to provide a current characteristic voltage;
an analog-to-digital converter (ADC), coupled to the current sensing circuit, to provide current characteristic data based on the current characteristic voltage; and
a determination circuit, coupled to the ADC, and determining whether the display panel operates within a rated chromaticity range based on the current characteristic data, to provide a panel status signal.

2. The detection device of the display panel according to claim 1, wherein the current sensing circuit comprises:
a current sensing amplifier, amplifying a sensing voltage, to provide a current sensing voltage based on the panel total current;
a low-pass filter, coupled to the current sensing amplifier, to provide a filtered voltage based on the current sensing voltage;
a current characteristic extraction circuit, coupled to the low-pass filter, to provide the current characteristic voltage based on the filtered voltage.

3. The detection device of the display panel according to claim 2, wherein the current sensing circuit comprises:
a sensing resistor, coupled in series with the display panel between a system high voltage and a ground voltage, to provide the sensing voltage;
a first differential amplifier, having a positive input terminal receiving the sensing voltage, a negative input terminal, and an output terminal providing the current sensing voltage;
a first capacitor, coupled between the positive input terminal and the negative input terminal;
a second capacitor, coupled between the positive input terminal and the ground voltage; and
a third capacitor, coupled between the negative input terminal and the ground voltage.

4. The detection device of the display panel according to claim 2, wherein the low-pass filter comprises:
a first resistor, coupled between the current sensing voltage and the filtered voltage; and
a fourth capacitor, coupled between the filtered voltage and the ground voltage.

5. The detection device of the display panel according to claim 2, wherein the current characteristic extraction circuit comprises:
a second differential amplifier, having a positive input terminal receiving the filtered voltage, a negative input terminal, and an output terminal;
a first diode, having an anode coupled to the output terminal, and a cathode coupled to the negative input terminal;
a second resistor, coupled between the negative input terminal and the current characteristic voltage; and
a fifth capacitor, coupled between the current characteristic voltage and the ground voltage.

6. The detection device of the display panel according to claim 1, wherein when a difference between the current characteristic data and a panel preset value set at the factory for the display panel is less than a threshold value, the panel status signal indicates that the display panel operates within the rated chromaticity range, and when the difference between the current characteristic data and the panel preset value is greater than or equal to the threshold value, the panel status signal indicates that the display panel operates outside the rated chromaticity range.

7. The detection device of the display panel according to claim 1, wherein the current characteristic voltage reflects one of a maximum voltage, a minimum voltage, and an average value of a sensing voltage generated across a sensing resistor by the total panel current during a sensing period.

8. A detection method of a display panel installed on a front of a vehicle and displaying a car logo while the vehicle is running, the detection method comprising:
receiving, via a current sensing circuit, a total panel current flowing through the display panel, to provide a current characteristic voltage;
providing, via an analog-to-digital converter (ADC), current characteristic data based on the current characteristic voltage; and
determining, via a determination circuit, whether the display panel operates within a rated chromaticity range based on the current characteristic data, to provide a panel status signal.

9. The detection method of the display panel according to claim 8, wherein when a difference between the current characteristic data and a panel preset value set at the factory for the display panel is less than a threshold value, the panel status signal indicates that the display panel operates within the rated chromaticity range, and when the difference between the current characteristic data and the panel preset value is greater than or equal to the threshold value, the panel status signal indicates that the display panel operates outside the rated chromaticity range.

10. The detection method of the display panel according to claim 8, wherein the current characteristic voltage is one of a maximum voltage, a minimum voltage, and an average value of a sensing voltage generated across a sensing resistor by the total panel current during a sensing period.
